(19) United States
(12) Patent Application Publication
(10) Pub. No.: US 2007/0253577 A1
(43) Pub. Date: Nov. 1, 2007

(54) Equalizer bank with interference reduction

(75) Inventors: Kuo Hsin Yen, Hsinhua Township (TW); Chih Feng Lin, Hsinhua Township (TW); Kai Ting Lee, Hsinhua Township (TW)

Correspondence Address: OLIFF & BERRIDGE, PLC, P.O. BOX 19928, ALEXANDRIA, VA, 22320, US

(73) Assignee: HIMAX TECHNOLOGIES LIMITED, Hsinhua Township (TW)

(21) Appl. No.: 11/414,257

(22) Filed: May 1, 2006

(51) Int. Cl. H03G 5/00; H04B 3/14; H01P 9/00

(52) U.S. Cl. 381/103; 333/28 R

(57) ABSTRACT

An equalizer bank with interference reduction is disclosed. The equalizer bank with interference reduction comprises a front-shelving filter, a plurality of peak filters, a rear-shelving filter and a plurality of compensators. The center frequency and the quality factor of each compensator are designed intentionally to be identical to those of the corresponding peak filter. When a user selects a specific gain level, the corresponding parameters that determine the peak filter and the compensator are retrieved directly and a complex calculation is skipped. Therefore, an audio signal can be equalized more efficiently with lower hardware cost.

### BACKGROUND OF THE INVENTION

1. Field of the Invention

The present invention relates to an equalizer bank with interference reduction, and more particularly, to an equalizer bank with interference reduction using plural compensators and equipped with look-up tables.

2. Description of the Related Art

In digital audio processing, equalizers are required to attain spectral sound equalization. An equalizer bank comprises several equalization filters connected in series or in parallel, so that the equalization filters are adjusted to boost or reduce the value of the specific frequency bands. The most common equalization system is probably the tone controls that can be found on most stereo systems. They provide a quick and easy way to adjust the sound to suit a user's tastes and partially compensate for the furniture configuration in a room. The user will often find the knob controls labeled “bass” and “treble.” Each of those knob controls is associated with a special type of filter called a shelving filter, or more precisely, a low-pass shelving filter and a high-pass shelving filter, respectively. FIG. 1 shows a traditional equalizer bank 1 comprising a low-frequency shelving filter (i.e., a low-pass shelving filter) 10, three peak filters 121-123 and a high-frequency filter (i.e., a high-pass shelving filter) 13.

FIGS. 2(a) and 2(b) show the gain plots of the frequency responses of the low-frequency shelving filter 10 and the high-frequency shelving filter 13 in FIG. 1, respectively. Note that most filters have a gain that changes with frequency and the gain plots are of the frequency response magnitude, which shows the gain at each frequency component. A gain greater than one will boost the signal (three curves with gain above one in each of FIGS. 2(a) and 2(b)) and a gain less than one will cut the signal (three curves with gain below one in each of FIGS. 2(a) and 2(b)). With the shelving filters, users are boosting or cutting one portion of the audio spectrum while leaving the rest unaffected. The frequency where the frequency response makes the transition between the two levels of gain is called the cutoff frequency (refer to FIGS. 2(a) and 2(b)). A tone control could be designed that lets the user change this cutoff frequency in addition to the level of cut or boost, but this is usually fixed at the design stage and cannot be adjusted by the user. In addition to bass and treble controls, the user may find “mid” controls, such as the three-band equalizers (e.g., three peak filters 121-123 of FIG. 1) commonly found on mixers. The three peak filters 121-123 affect frequencies “in between” the highs and lows. The peak filter (121, 122 or 123) is often referred to as a band-pass filter. Again, it boosts or cuts a small portion of the audio spectrum without affecting the other frequency bands. FIG. 2(c) shows the gain plot of the frequency response of the peak filter (121, 122 or 123) in FIG. 1. The peak filter (121, 122 or 123) is defined by two other characteristics. One is the center frequency, or CF, at which the peak filter is at its maximum gain. The other is the quality factor, or Q, which is an indication of the sharpness of the peak filter. In general, the user is allowed to adjust the boost or cut, but the center frequency and quality factor are fixed.

FIGS. 3(a) and 3(b) show two gain plots of the overall frequency response of the traditional equalizer bank 1 of FIG. 1 with different gain settings. Referring to FIG. 3(a), curves b-d are the gain plots of the frequency responses of the three peak filters 121-123; curves a and e are the gain plots of the frequency responses of the low-frequency shelving filter 10 and the high-frequency shelving filter 13, respectively. Curve f is the superposition of the curves a-e, which is the gain plot of the overall frequency response of the traditional equalizer bank 1 of FIG. 1. Curve f indicates that the traditional equalizer bank 1 suffers from the problem of excessive gain accumulation. Similarly, in FIG. 3(b), curves b′-d+ are the gain plots of the frequency responses of the three peak filters 121-123; curves a′ and e′ are the gain plots of the frequency responses of the low-frequency shelving filter 10 and the high-frequency shelving filter 13, respectively. Curve f is the superposition of curves a′-e′, which is the gain plot of the overall frequency response of the traditional equalizer bank 1 of FIG. 1; the problem of excessive gain diminution is incurred. FIGS. 3(a) and 3(b) indicate that the traditional equalizer bank 1 suffers from the problems of excessive gain accumulation and excessive gain diminution, respectively. The above two problems result from the interference between filters of FIG. 1.

Therefore, it is necessary to develop a new equalizer bank with interference reduction, which is cost-effective and convenient to operate.

### SUMMARY OF THE INVENTION

One objective of the present invention is to provide an equalizer bank with interference reduction, by adding at least one compensator and adjusting the gain thereof to reduce the interference caused between filters.

Another objective of the present invention is to provide an equalizer bank with interference reduction, which provides a user with convenient operation to equalize the sound.

In order to achieve the above and other objectives, the present invention discloses an equalizer bank with interference reduction, which equalizes an audio signal, comprising a front-shelving filter, at least one peak filter, a rear shelving filter and at least one compensator. The front-shelving filter transforms the audio signal into a first signal. The peak filter transforms the first signal into a second signal. The rear-shelving filter transforms the second signal into a third signal. The compensator compensates for the third signal. The center frequency and the quality factor of each compensator are identical to those of each corresponding peak filter. The gain of each compensator is determined by interference to the corresponding peak filter caused by the surrounding filters thereof. The interference is retrieved from look-up tables. Each of the front-shelving filter, the rear-shelving filter, the peak filter and the compensator is implemented by a two-order IIR filter whose transfer function can be determined according to the given characteristic frequency, the given quality factor and the received/determined gain thereof. In addition, coefficients that define the transfer function are also retrieved from look-up tables.

Accordingly, when a user selects a specific gain level for the peak filter, the parameters that determine the peak filter and the corresponding compensator are retrieved directly and a complex calculation is skipped. Therefore, an audio signal can be equalized more efficiently with lower cost.

### BRIEF DESCRIPTION OF THE DRAWINGS

The invention will be described according to the appended drawings in which:

FIG. 1 shows a traditional equalizer bank;

FIGS. 2(a) and 2(b) show the gain plots of the frequency responses of the low- and high-frequency shelving filters, respectively;

FIG. 2(c) shows the gain plot of the frequency response of the peak filters shown in FIG. 1;

FIG. 3(a) shows the gain plot of the overall frequency response of FIG. 1 suffering from excessive gain accumulation;

FIG. 3(b) shows the gain plot of the overall frequency response of FIG. 1 suffering from excessive gain diminution;

FIG. 4 shows a block diagram of one embodiment of the equalizer bank of the present invention; and

FIG. 5 shows the Direct Form to express a two-order IIR transfer function.

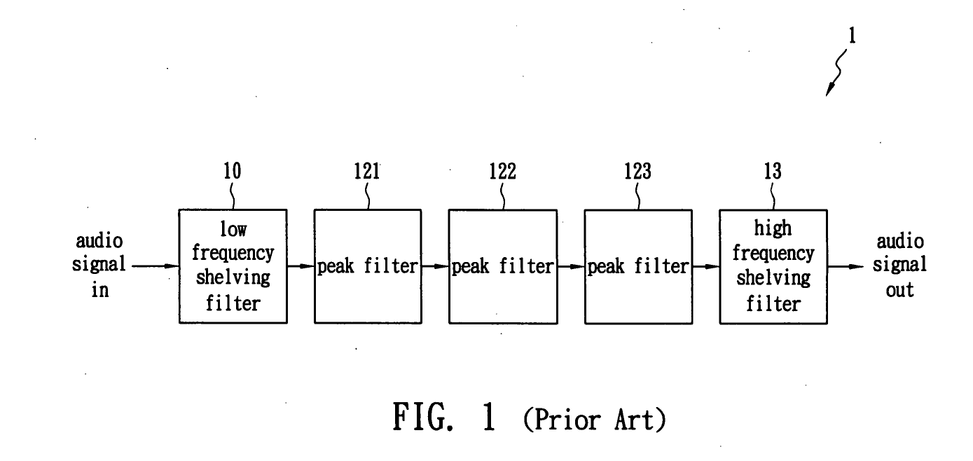

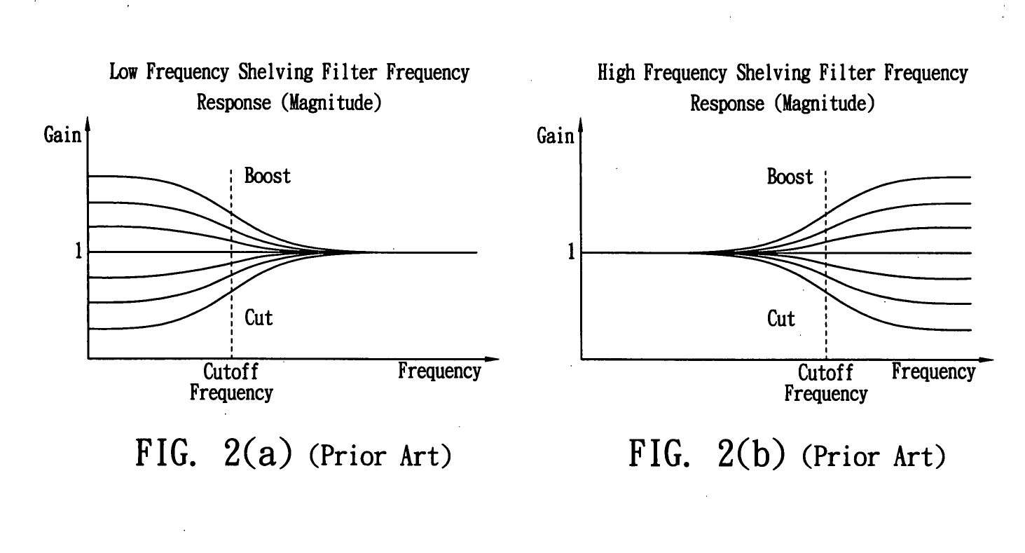

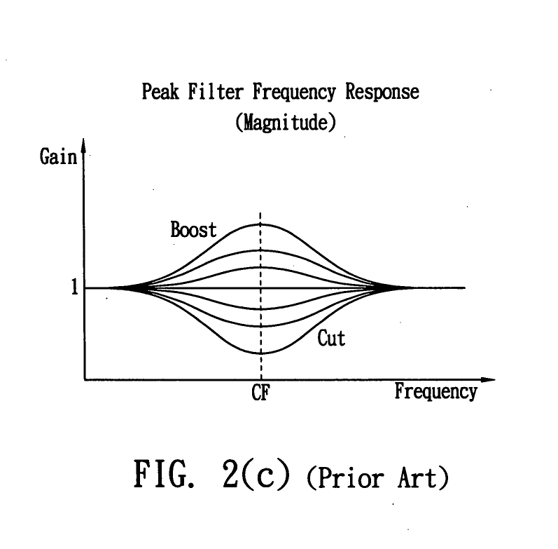

### DETAILED DESCRIPTION OF THE INVENTION

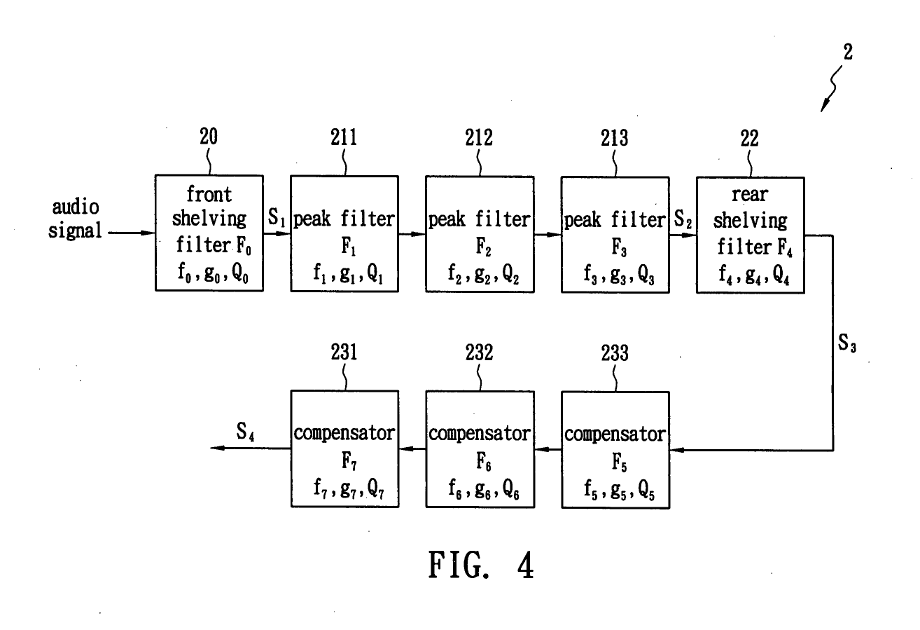

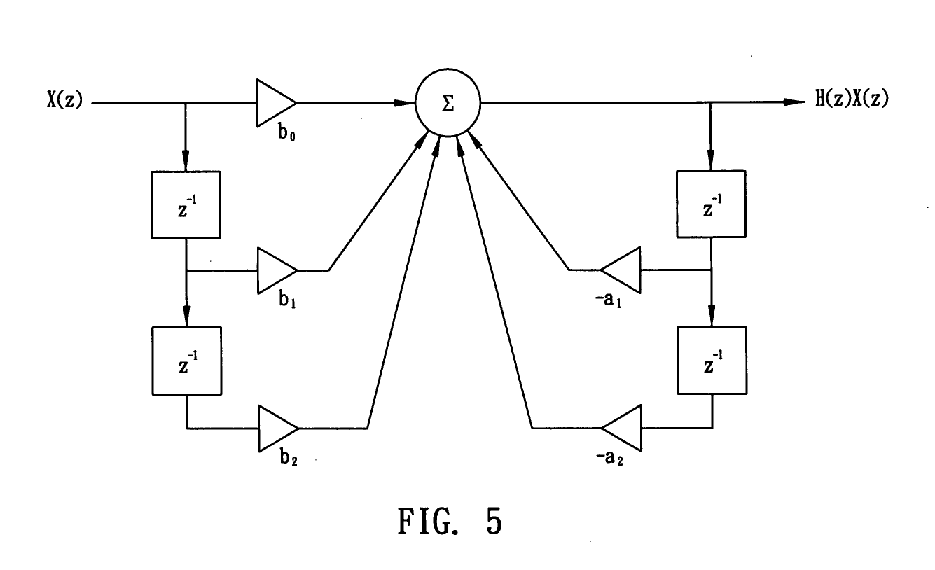

FIG. 4 shows a block diagram of one embodiment of the equalizer bank 2 of the present invention, which comprises a front-shelving filter 20 characterized by a cutoff frequency f₀, a gain g₀ and a quality factor Q₀, three peak filters 211-213 characterized by center frequencies f₁, f₂ and f₃, gains g₁, g₂ and g₃, and quality factors Q₁, Q₂ and Q₃, a rear-shelving filter 22 characterized by a cutoff frequency f₄, a gain g₄ and a quality factor Q₄, and three compensators 231-233 characterized by center frequencies f₅, f₆ and f₇, gains g₅, g₆ and g₇, and quality factors Q₅, Q₆ and Q₇. An audio signal is fed to the front-shelving filter 10 and transformed into a first signal S₁. Then the three peak filters 211-213 transform the first signal S₁ into a second signal S₂. The rear-shelving filter 22 transforms the second signal S₂ into a third signal S₃ that exhibits excessive gain accumulation or excessive gain diminution. Afterwards, the three compensators 231-233 compensate for the third signal S₃ to reduce the excessive gain accumulation or excessive gain diminution and then generate a fourth signal S₄ as the output signal.

The cutoff frequency (f₀ or f₄) for the shelving filter (20 or 22) and the center frequency (f₁, f₂, or f₃) for the peak filter (211, 212 or 213) can be called the characteristic frequency. Note that the characteristic frequencies of the front-shelving filter 20, the peak filters 211-213 and the rear-shelving filter 22 are fixed and arranged in order. That is, one of the two relations, f₀>f₁>f₂>f₃>f₄ or f₀<f₁<f₂<f₃<f₄, is met. Each of the front-shelving filter 20, the three peak filters 211-213 and the real-shelving filter 22 is implemented by a two-order IIR filter whose transfer function can be defined as equation (1), which contains five coefficients (i.e., five unknowns) to be determined.

$$H ( z ) = \frac{{b}_{0} + {b}_{1} {Z}^{- 1} + {b}_{2} {Z}^{- 2}}{1 + {a}_{1} {Z}^{- 1} + {a}_{2} {Z}^{- 2}} \qquad ( 1 )$$

FIG. 5 shows the Direct Form commonly used to express equation (1), where X(z) is the z-transform of the input X(t), and a₁, a₂, b₀, b₁ and b₂ are five coefficients to be determined. If the peak filter (211, 212 or 213) is designed to be a parametric equalizer to boost or cut the gain, the five coefficients to determine H(z) can be uniquely determined from complex calculations for a given characteristic frequency and a given quality factor.

To simplify the complex calculations in obtaining the five coefficients, the gain of the peak filter (e.g., the shelving filter 20 or 22 or the peak filters 211-213) is divided into several gain levels, each corresponding to a set of coefficients obtained from the complex calculations. Afterwards, the gain levels and the corresponding sets of coefficients regarding the peak filter are stored in a gain table for each peak filter. When the user moves a knob control of the peak filter to select a specific gain level, the corresponding set of coefficients is retrieved directly from the gain table and the five coefficients regarding the peak filter is determined. Therefore, the complex calculation is omitted and the equalization efficiency of the sound is improved. Table 1 below shows an embodiment of the gain table of the filter.

TABLE 1

| Gain (dB) | a₁ | a₂ | b₀ | b₁ | b₂ |
|---|---|---|---|---|---|
| 12 | A₁₂₋₁ | A₁₂₋₂ | B₁₂₋₀ | B₁₂₋₁ | B₁₂₋₂ |
| 11 | A₁₁₋₁ | A₁₁₋₂ | B₁₁₋₀ | B₁₁₋₁ | B₁₁₋₂ |
| . . . | . . . | . . . | . . . | . . . | . . . |
| −11 | A₋₁₁₋₁ | A₋₁₁₋₂ | B₋₁₁₋₀ | B₋₁₁₋₁ | B₋₁₁₋₂ |
| −12 | A₋₁₂₋₁ | A₋₁₂₋₂ | B₋₁₂₋₀ | B₋₁₂₋₁ | B₋₁₂₋₂ |

In Table 1, all the coefficients (from A₁₂₋₁ to A₋₁₂₋₁, from A₁₂₋₂ to A₋₁₂₋₂, from B₁₂₋₀ to B₋₁₂₋₀, from B₁₂₋₁ to B₋₁₂₋₁ and from B₁₂₋₂ to B₋₁₂₋₂) are obtained in advance from the complex calculation at the design stage, and the gain of the peak filter is divided into plural gain levels (25 gain levels in the current embodiment; that is, from 12 dB to −12 dB). For example, the user can select a specific gain level (e.g., 12 dB) and the corresponding set of coefficients (e.g., from A₁₂₋₁ to B₁₂₋₂) can be retrieved directly from the gain table to determine the peak filter.

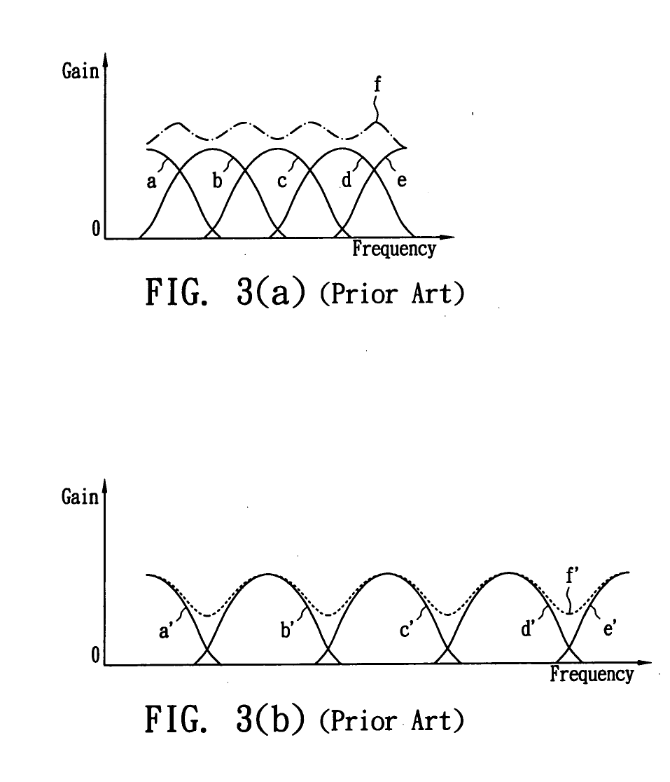

The design of the three compensators 231-233 of FIG. 4 is described in detail below. Assuming that the gain plots of the frequency responses of the front-shelving filter 20, the three peak filters 211-213 and the rear-shelving filter 22 are represented by curves a, b, c, d and e of FIG. 3(a), respectively, these result in the problem of excessive gain accumulation. Referring to FIG. 4, the center frequency f₅, the gain g₅ and the quality factor Q₅ are designed according to equations (2)-(4) below.
f₅=f₃ (2)
Q₅=Q₃ (3)
g₅=−(|H₂₃(z)|+|H₄₃(z)|) when the frequency=f₃ (4)

where |H₂₃(z)| is the interference of the peak filter 212 (F₂) to the peak filter 213 (F₃) at frequency f₃, and |H₄₃(z)| is the interference of the rear-shelving filter 22 (F₄) to the peak filter 213 (F₃) at frequency f₃. That is, the gain of the compensator 233(i.e., F₅) is used to compensate for the interference (|H₂₃(z)| and |H₄₃(z)|) caused by two filters connected next to the corresponding peak filter 213 (F₃). In the current embodiment, only two filters (i.e., F₂ and F₄) that are connected next to the corresponding peak filter (i.e., F₃) and contribute the interference are considered, but the number of the filters contributing the interference is not limited in practice. That is, more than two interferences to the corresponding peak filter (e.g., F₃) caused by the surrounding filters (e.g., all the peak filters, the front-shelving filter and the rear-shelving filters (F₀, F₁, F₂, F₄) except the corresponding peak filter (F₃) may be considered when designing the compensator.

Two interference tables for each compensator are designed to store the gain levels and the corresponding interferences to the corresponding peak filter caused by the two filters connected next to the corresponding peak filter. The gain levels used in the two interference tables are designed intentionally to be identical to the gain levels used in the gain table such as Table 1. Tables I₂₃ and I₄₃ below are embodiments of two interference tables for the compensator 233(F₅).

| | |
|---|---|
| Table I₂₃ | Table I₄₃ |

| Gain (dB) | Interference value | Gain (dB) | Interference value |
|---|---|---|---|
| 12 | IV₁₂₋₂₃ | 12 | IV₁₂₋₄₃ |
| 11 | IV₁₁₋₂₃ | 11 | IV₁₁₋₄₃ |
| . . . | . . . | . . . | . . . |
| −11 | IV₋₁₁₋₂₃ | −11 | IV₋₁₁₋₄₃ |
| −12 | IV₋₁₂₋₂₃ | −12 | IV₋₁₂₋₄₃ |

Table I₂₃ stores a plurality of gain levels (25 gain levels in the current embodiment; that is, from 12 dB to −12 dB) and the corresponding interferences (25 interferences in the current embodiment; that is, from IV₁₂₋₂₃ to IV₋₁₂₋₂₃) of the peak filter 212 (F₂) to the peak filter 213 (F₃). Similarly, Table I₄₃ stores a plurality of gain levels (25 gain levels in the current embodiment; that is, from 12 dB to −12 dB) and the corresponding interferences (25 interferences in the current embodiment; that is, from IV₁₂₋₄₃ to IV₋₁₂₋₄₃) of the rear-shelving filter 22 (F₄) to the peak filter 213 (F₃). All the interferences in the interference tables are pre-calculated. With the interference tables, when a specific gain level of a peak filter (e.g., F₃) is selected by the user, the interferences to and the gain of the associated compensator (e.g., F₅) are defined simultaneously.

For the other two compensators 232 (F₆) and 231 (F₇), their center frequencies, quality factors and gains satisfy equations (5)-(10) below.
f₆=f₂ (5)
Q₆=Q₂ (6)
g₆=−(|H₁₂(z)|+|H₃₂(z)|) when the frequency=f₂ (7)
f₇=f₁ (8)
Q₇=Q₁ (9)
g₇=−(|H₀₁(z)|+|H₂₁(z)|) when the frequency=f₁ (10)

where |H₁₂(z)| is the interference of the peak filter 211 (F₁) to the peak filter 212 (F₂) at frequency f₂, and |H₃₂(z)| is the interference of the peak filter 213 (F₃) to the peak filter 212 (F₂) at frequency f₂; |H₀₁(z)| is the interference of the front-shelving filter 20 (F₀) to the peak filter 211 (F₁) at frequency f₁, and |H₂₁(z)| is the interference of the peak filter 212 (F₂) to the peak filter 211 (F₁) at frequency f₁.

Afterwards, each of the three compensators (231, 232 or 233) can be implemented by an IIR filter whose transfer function is determined by the characteristic frequency, the quality factor and the gain determined as equations (2)-(10). Since the characteristic frequency and the quality factor of each compensator are identical to those of each corresponding peak filter, the compensator and the corresponding peak filter can share the same gain table in determining the five coefficients.

So far, we have presented how to design the center frequencies, the quality factors and the gains of the three compensators of FIG. 4 for the problem of excessive gain accumulation (refer to FIG. 3(a)). For the case of excessive gain diminution (refer to FIG. 3(b)), the same design methodology is followed. All the interferences are pre-calculated at the design stage, and then are stored in the interference tables for each of the compensators. Since the gain levels in the two interference tables (e.g., Tables I₂₃ and I₄₃) of the compensator (e.g., F₅) are designed intentionally to be identical to the gain levels in the gain table of the corresponding peak filter (e.g., F₃), the user only selects a specific gain level of a peak filter, and all the related information (i.e., five coefficients of the peak filter and the corresponding compensator) is obtained immediately to equalize the sound.

Each filter in the equalizer bank of the present invention can be implemented by software (i.e., programming languages) or by hardware (i.e., real circuits including memories).

The above-described embodiments of the present invention are intended to be illustrative only. Numerous alternative embodiments may be devised by those skilled in the art without departing from the scope of the following claims.

What is claimed is:

1. An equalizer bank with interference reduction for equalizing an audio signal, comprising:
a front-shelving filter transforming the audio signal into a first signal;
at least one peak filter transforming the first signal into a second signal;
a rear-shelving filter transforming the second signal into a third signal; and
at least one compensator corresponding to the at least one peak filter and compensating for the third signal, wherein a characteristic frequency and a quality factor of each compensator are identical to those of the corresponding peak filter, and wherein a gain of each compensator is determined by interferences to the corresponding peak filter.

2. The equalizer bank with interference reduction of claim 1, wherein each of the front-shelving filter, the rear-shelving filter, the compensator and the peak filters is implemented by a two-order infinite impulse response (IIR) filter.

3. The equalizer bank with interference reduction of claim 2, wherein coefficients to determine the transfer function of the two-order IIR transfer function are retrieved from a gain table.

4. The equalizer bank with interference reduction of claim 3, wherein the gain table associates a plurality of gain levels and a plurality of corresponding sets of the coefficients regarding the transfer function of the two-order IIR filter.

5. The equalizer bank with interference reduction of claim 1, wherein the gain of each compensator compensates for interferences to the corresponding peak filter caused by part or all of the peak filters, the front-shelving filter and the rear-shelving filter.

6. The equalizer bank with interference reduction of claim 1, wherein the gain of each compensator compensates for the interferences to the corresponding peak filter caused by the two peak filters connected next to the corresponding peak filter.

7. The equalizer bank with interference reduction of claim 6, wherein the interferences to the corresponding peak filter caused by the two peak filters connected next to the corresponding peak filter are the magnitudes of the two peak filters connected next to the corresponding peak filter at the characteristic frequency thereof.

8. The equalizer bank with interference reduction of claim 6, wherein the gain of each compensator is equal to the inverse of the sum of the magnitudes of the two peak filters connected next to the corresponding peak filter at the characteristic frequency thereof.

9. The equalizer bank with interference reduction of claim 4, wherein each compensator associates with two interference tables, each comprising the plurality of gain levels and a plurality of corresponding interferences to the corresponding peak filter caused by each of the two peak filters connected next to the corresponding peak filter.

10. The equalizer bank with interference reduction of claim 9, wherein the compensator and corresponding peak filter share the same gain table when determining the transfer function thereof.

11. The equalizer bank with interference reduction of claim 1, which is implemented by software.

12. The equalizer bank with interference reduction of claim 1, which is implemented by hardware.

13. The equalizer bank with interference reduction of claim 1, wherein the characteristic frequencies of the front-shelving filter, the peak filters and the rear-shelving filter are arranged in order.

14. The equalizer bank with interference reduction of claim 1, wherein each peak filter and the corresponding compensator are defined simultaneously when a gain level of the peak filter is selected.
